(19) United States
(12) Patent Application Publication
(10) Pub. No.: US 2024/0186286 A1
(43) Pub. Date: Jun. 6, 2024

(54) DEVICE FOR ACQUIRING A 2D IMAGE AND A DEPTH IMAGE OF A SCENE

(71) Applicant: Commissariat à I'Énergie Atomique et aux Énergies Alternatives, Paris (FR)

(72) Inventors: Jérôme Vaillant, Grenoble Cedex 9 (FR); Jacques Baylet, Grenoble Cedex 9 (FR)

(73) Assignee: Commissariat à I'Énergie Atomique et aux Énergies Alternatives, Paris (FR)

(21) Appl. No.: 18/526,011

(22) Filed: Dec. 1, 2023

(30) Foreign Application Priority Data
Dec. 6, 2022 (FR) 2212848

(51) Int. Cl. H01L 25/04; H01L 27/146

(52) U.S. Cl. CPC H01L 25/043; H01L 25/042; H01L 27/14621; H01L 27/14627; H01L 27/14689; H01L 27/1469

(57) ABSTRACT

A method of manufacturing a device for acquiring a 2D image and a depth image, the method comprising the following steps: a) forming, on a first face of a first support semiconductor substrate, a first sensor comprising a plurality of depth pixels; b) forming, in the first support substrate, on the side of a second face of the first substrate opposite the first face, at least one optical concentrator; c) forming, in and on a second semiconductor substrate, a second sensor comprising a plurality of 2D image pixels; and d) placing the second sensor right next the first support substrate on the side of the second face of the first support substrate.

### CROSS REFERENCE TO RELATED APPLICATIONS

This application claims priority to French application number 2212848, filed Dec. 6, 2022, the contents of which is incorporated by reference in its entirety.

### TECHNICAL FIELD

The present description relates generally to image acquisition devices. More particularly, the present description relates to image acquisition devices adapted to acquire a 2D visible image and a depth image of a scene.

### BACKGROUND ART

Devices for acquiring depth images of a scene, such as Time of Flight (ToF) sensors for a light signal emitted towards the scene, and then reflected back towards the sensor by objects in the scene, have been proposed. In addition, structured light sensors projecting a pattern such as fringes or a grid onto the scene, and capturing an image of this pattern distorted by the relief of the objects in the scene to estimate their distance from the sensor, have been proposed.

In some applications, it would be desirable to be able to simultaneously acquire a 2D visible image and a depth image of the same scene. One solution to achieve this is to provide separate image sensors, placed side by side, to acquire the 2D image and the depth image. A drawback of this solution is that it implies that the image sensors have different points of view of the scene, resulting in misalignment between the pixels of the corresponding images and an increase in the cost and size of the device.

### SUMMARY OF THE INVENTION

It would be desirable to have a device for acquiring a 2D image and a depth image of a scene that at least partially addresses one or more of the drawbacks of known devices.

To this end, one embodiment provides a method of manufacturing a device for acquiring a 2D image and a depth image, the method comprising the following steps:
a) forming, on a first face of a first support semiconductor substrate, a first sensor comprising a plurality of depth pixels;
b) forming, in the first support substrate, on the side of a second face of the first substrate opposite the first face, at least one optical concentrator;
c) forming, in and on a second semiconductor substrate, a second sensor comprising a plurality of 2D image pixels; and
d) placing the second sensor right next the first support substrate on the side of the second face of the first support substrate.

According to one embodiment, in step a), photodiodes of the depth pixels of the first sensor are formed in a region of semiconductor material.

According to one embodiment, the material of said region is a III-V or II-VI semiconductor.

According to one embodiment, said region is made of indium gallium arsenide.

According to one embodiment, said region is attached to the first support substrate, on the side of the first face of the first support substrate, prior to forming the depth pixel photodiodes.

According to one embodiment, said region is attached to the first support substrate via an oxide layer.

According to one embodiment, the method further comprises, between steps a) and b), a step of bonding the first sensor, on the first side of the first support substrate, to an interconnect stack forming part of a third CMOS substrate.

One embodiment provides a device for acquiring a 2D image and a depth image, comprising:
a first sensor formed on a first face of a first support semiconductor substrate, the first sensor comprising a plurality of depth pixels, and at least one optical concentrator formed in the first support substrate, on the side of a second face of the first support substrate opposite the first face; and
attached to the first support substrate, on the side of the second face of the first support substrate, a second sensor formed in and on a second semiconductor substrate and comprising a plurality of 2D image pixels.

According to one embodiment, each optical concentrator is a refractive microlens, a diffractive microlens, a Fresnel microlens, or a metasurface.

According to one embodiment, the second sensor is a colour image sensor, with each 2D image pixel comprising a colour filter preferentially transmitting red, green or blue light.

According to one embodiment, the first and second substrates are made of monocrystalline silicon.

According to one embodiment, the depth pixels of the first sensor have a larger pitch than the 2D image pixels of the second sensor.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial, schematic cross-sectional view of an example device for acquiring a 2D image and a depth image of a scene according to one embodiment; and

FIG. 2A, FIG. 2B, FIG. 2C, FIG. 2D, FIG. 2E, FIG. 2F, and FIG. 2G are schematic, partial cross-sectional views illustrating steps of an example method for manufacturing the device shown in FIG. 1 according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the design of the photodiodes and pixel control circuits has not been detailed, as the design of such pixels is within the ability of those skilled in the art on the basis of the indications in the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

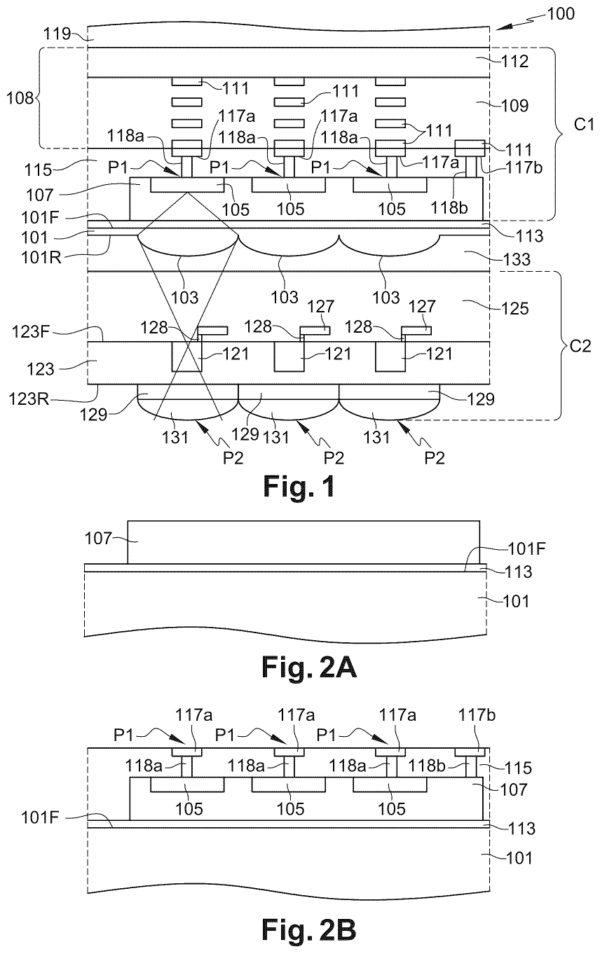

FIG. 1 is a partial, schematic cross-sectional view of an example device 100 for acquiring a 2D image and a depth image of a scene according to one embodiment.

The device 100 of FIG. 1 comprises:
a first sensor C1 arranged on a first face 101F of a first support semiconductor substrate 101 (the upper face of the substrate 101, in the orientation of FIG. 1), the first sensor C1 comprising a plurality of depth pixels P1;
at least one optical concentrator 103 formed in the support substrate 101, on the side of a second face 101R of the substrate 101 (the lower face of the substrate 101, in the orientation of FIG. 1) opposite the first face 101F; and
attached to the support substrate 101, on the side of the second face 101R of the substrate 101, a second sensor C2 comprising a plurality of 2D image pixels P2.

In the example shown, the substrate 101 acts as a mechanical bracket for the sensor C1, and in particular has no electrical function. By way of example, the support substrate 101 is made of monocrystalline silicon.

In the present description, the term “front face” of a substrate refers to the face of the substrate on which an interconnection stack associated with elements formed in and/or on the substrate is made, while the term “rear face” of a substrate refers to the face of the substrate opposite its front face.

In practice, the device 100 is intended for use in combination with a light source emitting radiation in a range of wavelengths detected by the depth pixels of sensor C1, for example an infrared source. In the case of time-of-flight (ToF) depth measurement, the light source is, for example, a laser source emitting at a wavelength, or in a narrow wavelength range, outside the visible range, for example in the short-wave infrared (SWIR). By way of example, the light source is a laser source the main emission peak of which has a central wavelength of between 700 and 1,500 nm, preferably between 1,100 and 1,500 nm, and a full width at half maximum of the order of a few nanometres, for example less than 3 nm. In operation, the light signal produced by the light source is emitted towards the scene (e.g. via one or more lenses), in the form of light pulses, e.g. periodic pulses. The return light signal reflected by the scene is captured by the depth pixels P1 of the sensor C1, so as to measure the time of flight of the light signal at different points in the scene, and to deduce the distance to the acquisition device at different points in the scene. Alternatively, pixels P1 of sensor C1 can be used to measure depth using structured light. The pixels P2 of the sensor C2, on the other hand, are capable of capturing radiation in a wavelength range below 1,100 nm. For example, the pixels P2 capture visible light emitted by the scene, in a wavelength range between 400 and 700 nm, to form a 2D image of the scene.

In the example shown, each pixel P1 of the sensor C1 comprises a photodiode 105 having one or more localized implanted regions formed in a semiconductor region 107. In this example, the one or more implanted regions are arranged on the face 101F of the substrate 101, and extend vertically through the thickness of the semiconductor region 107 from the side of the region 107 opposite the substrate 101 (the top side of the region 107, in the orientation of FIG. 1).

In the illustrated example, the sensor C1 also comprises a CMOS (Complementary Metal-Oxide-Semiconductor) substrate 108, for example comprising an interconnection stack 109, made of alternating dielectric and conductive layers, in which are formed contact elements 111, for example, electrical connection tracks and/or terminals, and a read circuit 112, arranged on the side of a face of the interconnection stack 109 opposite the substrate 101, in which transistors for reading and addressing the pixels P1 of the sensor C1 are formed (these transistors have not been illustrated in FIG. 1 so as not to overload the drawing). Circuit 112 is, for example, a Read-Out Integrated Circuit (ROIC). A peripheral circuit (not shown) for controlling and supplying the pixels P1 of the sensor C1 may also be formed in the CMOS substrate 108. Although not detailed in FIG. 1, the contact elements 111 can be interconnected by conductive vias.

In the example shown in FIG. 1, the face 101F of the semiconductor substrate 101 is coated with a layer 113, for example a layer transparent to the operating wavelengths of the pixels P1. The semiconductor region 107 coats a portion of the face of layer 113 opposite the substrate 101 (the top face of layer 113, in the orientation of FIG. 1). In the example shown, the sides and top face of semiconductor region 107 are coated with an electrically insulating layer 115.

For example, contact elements 117a, arranged in line with the photodiodes 105, and a contact element 117b, arranged in line with an area of the semiconductor region 107 devoid of photodiode 105, are formed inside the insulating layer 115. In the orientation of in FIG. 1, the contact elements 117a and 117b are flush with the top of the insulating layer 115. In the example shown, each contact pickup element 117a is connected to an underlying photodiode 105, for example via a conductive via 118a extending vertically in the insulating layer 115 from the contact pickup element 117a to the corresponding photodiode 105, and the contact element 117b is connected to the semiconductor region 107, for example via a conductive via 118b extending vertically in the insulating layer 115 from the contact element 117b to the semiconductor region 107.

Alternatively, contact element 117b can be connected, via the via 118b, to a transparent, electrically conductive layer, for example acting as a common electrode for photodiodes 105, interposed between the semiconductor region 107 and the transparent layer 113. In this case, the transparent, conductive layer is made of a transparent, conductive oxide, such as Indium Tin Oxide (ITO).

In the example shown, the CMOS substrate 108 of sensor C1 coats the face of insulating layer 115 opposite substrate 101 (the upper side of layer 115, in the orientation of FIG. 1). Contact pickup elements 111 of the CMOS substrate 108 contact the contact pickup elements 117a and 117b, for example to link or connect each photodiode 105 of the sensor C1 to the readout circuit 112.

Optionally, a further CMOS substrate 119 can, as in the example shown in FIG. 1, be arranged on and in contact with the face of the CMOS substrate 108 opposite the semiconductor substrate 101 (the top face of the CMOS substrate 108, in the orientation of FIG. 1). Although not detailed in FIG. 1, an interconnection stack as well as circuits for storing and processing signals associated with the pixels P1 and P2 of the sensors C1 and C2 can be formed in the CMOS substrate 119.

In the illustrated example, each pixel P2 of the sensor C2 comprises a photodiode 121 having one or more localized implanted regions formed in a semiconductor substrate 123, for example a monocrystalline silicon substrate. In this example, the one or more implanted regions of the photodiode 121 are arranged on the side of a front face 123F of the substrate 123 (the top face of the substrate 123, in the orientation of FIG. 1). Each pixel P2 may further comprise one or more additional components (not shown), for example read and address transistors, formed on the side of the front face 123F of the substrate 123, for example in the substrate 123 and on the front face 123F of the substrate 123. The sensor C2 further comprises an interconnection stack 125 made of alternating dielectric and conductive layers coating the front face 123F of the substrate 123, in which are formed contact elements 127, for example electrical connection tracks and/or terminals, connecting the pixels P2 of the sensor C2 to a peripheral control and supply circuit (not shown). As shown in FIG. 1, each photodiode 121 is connected to an overlying contact element 127 by a conductive via 128, for example.

The sensor C2 is, for example, a 2D colour image sensor, i.e. it comprises pixels P2 of different types, adapted to measure light intensities in distinct visible wavelength ranges. To this end, each pixel P2 comprises a colour filter 129, for example a layer of coloured resin, arranged on the side of the rear face 123R of the substrate 123. By way of example, the sensor C2 comprises three types of pixel P2. For example, the sensor C2 comprises first pixels P2 called blue pixels, the colour filter 129 of which preferentially transmits blue light, second pixels P2 called red pixels, the colour filter 129 of which preferentially transmits red light, and third pixels P2 called green pixels, the colour filter 129 of which preferentially transmits green light. In FIG. 1, the different types of pixels P2 are not differentiated. By way of example, the colour filters 129 form a Bayer matrix.

In the illustrated example, each pixel P2 of the sensor C2 further comprises a microlens 131 arranged on the side of the rear face 123F of the substrate 123, for example on and in contact with the pixel colour filter 129, adapted to focus incident light onto the photodiode 121 of the underlying pixel P2.

In this example, the sensor C1 is bonded to the sensor C2 by molecular bonding. For this purpose, an electrically insulating layer 133, made of silicon oxide for example, is arranged on the side of the face 101R of the substrate 101, and coats the optical concentrators 103 in particular. The face of the insulating layer 133 opposite the substrate 101 (the lower face of the layer 133, in the orientation of FIG. 1) is brought into contact with the face of the interconnection stack 125 opposite the substrate 123, so as to achieve molecular bonding of the sensor C2 to the sensor C1 (or of the sensor C1 to the sensor C2). By way of example, the dielectric layers of the interconnection stack 125 of the sensor C2 are made of the same material as layer 133, for example silicon oxide.

In the device 100 shown in FIG. 1, for example, the depth pixels P1 are individually controlled to produce a depth image with a resolution equal to the number of pixels P1 in the sensor C1.

In the example shown, device 100 has as many depth pixels P1 in sensor C1 as 2D image pixels P2 in sensor C2. However, this example is not limitative, those skilled in the art being able, from the indications of the present description, to adapt the embodiments described to a case where the sensor C1 of the device 100 includes any proportion of the pixels P1 with respect to the pixels P2 of the sensor C2, for example one depth pixel P1 for each group of four visible image pixels P2 of the sensor C2.

Furthermore, although only three depth pixels P1 and three 2D image pixels P2 have been shown in FIG. 1, the device 100 can of course have more than three pixels P1 and pixels P2. By way of example, the device 100 comprises several thousand or several million pixels P1, and several thousand or several million pixels P2.

Furthermore, although the depth sensor C1 and 2D image sensor C2 in the example shown have substantially identical pitches of the pixels P1 and P2, this example is not limitative, as the sensors C1 and C2 can have any pitch of pixel. In the present description, the term “pitch of pixel” corresponds, for example, to the centre-to-centre distance between two adjacent pixels forming part of the same sensor. By way of example, the pitch of the pixels P1 of the sensor C1 is greater than, for example twice, the pitch of the pixels P2 of the sensor C2. In this case, when viewed from above, the pixels P1 have a surface area larger than that of the pixels P2, and the sensor C1 includes, for example, four times fewer pixels P1 than the sensor C2 includes pixels P2.

One advantage of the device 100 is that the superimposition of depth sensors C1 and 2D image sensors C2 enables a reduction in size compared with a case where depth sensors and 2D image sensors placed side by side would be used. Another advantage of the device 100 lies in the fact that it allows the use of a semiconductor material other than silicon to produce the pixels P1 of the sensor C1, for example a material better suited to capture the wavelength of illumination of the scene by the light source, particularly in a case where the wavelength of illumination is greater than 1,100 nm, i.e. beyond the sensitivity range of silicon. Furthermore, the provision of optical concentrators 103 between the 2D image pixels P2 of the sensor C2 and the depth pixels P1 of the sensor C1 advantageously allows optimizing the transmission of radiation received from the rear face 123R of the sensor C2 to the photodiodes 105 of the pixels P1 of the sensor C1. More precisely, the optical concentrators 103 of the sensor C1 allow the radiation received from the face 123R to be better focused on the photodiodes 105.

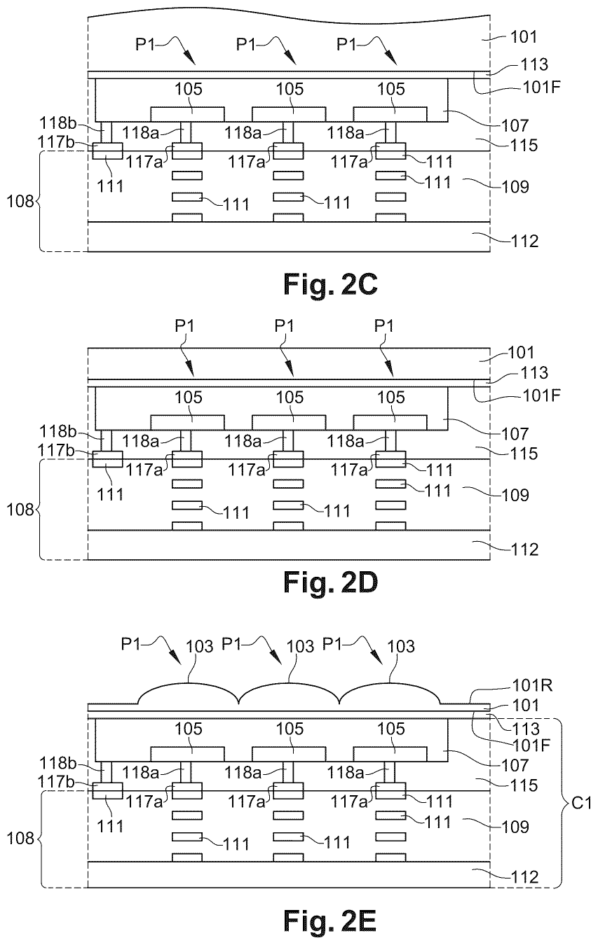

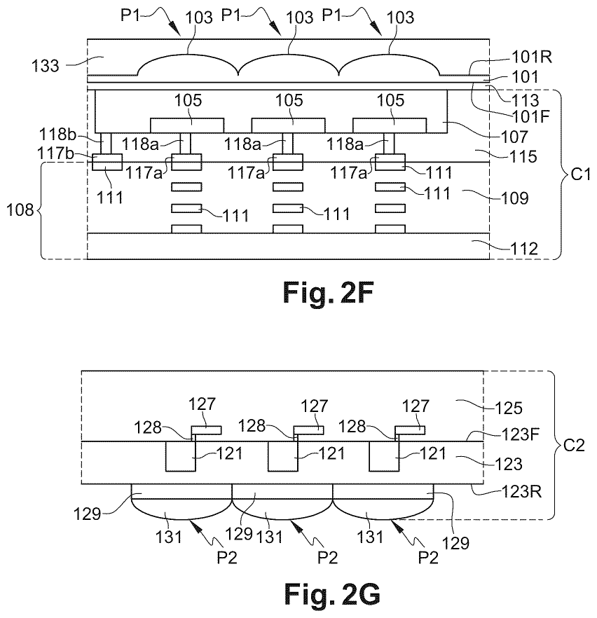

FIG. 2A, FIG. 2B, FIG. 2C, FIG. 2D, FIG. 2E, FIG. 2F, and FIG. 2G are schematic, partial cross-sectional views illustrating steps, for example successive steps, of an example method for manufacturing the device 100 of FIG. 1 according to one embodiment.

In particular, FIG. 2A illustrates a step for transferring the semiconductor region 107 onto the semiconductor substrate 101, on the side of the face 101F of the substrate 101. In the example shown, the region 107 is bonded to the face 101F of the substrate 101 by means of the transparent layer 113. The face 101F of the substrate 101 is coated with the transparent layer 113, which in turn is partially coated, after bonding, with semiconductor region 107. The semiconductor region 107 is fixed on the face 101F of the substrate 101, via the layer 113, in a “final” bond. In other words, the substrate 101 is not intended to be dissociated from the semiconductor region 107 during subsequent steps in the method for manufacturing the device 100. One advantage of permanently bonding the region 107 to the substrate 101, as opposed to temporarily bonding and removing the substrate 101 during the method for manufacturing the device 100, is that larger thermal budgets can be used during subsequent steps in the method.

The bonding layer 113 is an oxide layer, for example a silicon oxide layer. Layer 113 may have a monolayer or multilayer structure, e.g. an oxide/nitride bilayer structure comprising a silicon nitride layer coating the face 101F of substrate 101 and a silicon oxide layer coating the silicon nitride layer. More generally, those skilled in the art is able to provide one or more layers of dielectric materials for bonding the region 107 to the substrate 101. Those skilled in the art is also able to determine the thicknesses of this layer or these layers so as to optimize bonding and optical properties, for example to obtain an anti-reflective function at the detection wavelength of the pixels P1 of the sensor C1.

The region 107 is generally made of a material that is incompatible with CMOS-type processes. The material of region 107 is, for example, an inorganic semiconductor material, e.g. a III-V compound comprising at least a first Group III element, a second Group V element and, optionally, a third element, e.g. a Group III element other than the first element. By way of example, the material in region 107 is indium gallium arsenide (chemical formula InGaAs or InₓGa₁₋ₓAs). Alternatively, the material of the region 107 may be a II-VI compound comprising at least a first Group II element, a second Group VI element and, optionally, a third element, for example a Group II element other than the first element.

In particular, FIG. 2B illustrates subsequent steps of forming the photodiodes 105 of the pixels P1 of the sensor C1, and producing the insulating layer 115.

Photodiodes 105 are formed in the semiconductor region 107, for example, by a process of masking and then diffusing doping species, such as zinc atoms. Alternatively, photodiodes 105 can be formed by ion implantation on the side of the face 101F of the substrate 101.

The insulating layer 115 is then deposited on the structure on the side of the face 101F of the substrate 101 and planarized, for example by Chemical and Mechanical Polishing (CMP). The conductive vias 118a and 118b and the contact elements 117a and 117b are then formed in the layer 115, for example by at least one step of photolithography and then etching, so as to form cavities in layer 115, followed by at least one step of filling these cavities with a conductive material, for example a metal or metal alloy. By way of example, each photodiode 105 comprises, at the end of these steps, a first individual electrode, for example an electrode constituted by one of the contact elements 117a, and a second electrode, for example an electrode constituted by the contact element 117b, the second electrode being for example common to several or all the photodiodes 105 of the sensor C1.

In particular, FIG. 2C illustrates a subsequent step of transferring the structure previously described in relation to FIG. 2B to the CMOS substrate 108, for example by hybrid bonding.

In the example shown, the face of the layer 115 opposite the substrate 101 is placed in contact with the face of interconnect stack 109 of the CMOS substrate 108 opposite the readout circuit 112. In the illustrated example, the contact elements 117a and 117b flush with the face of the layer 115 opposite the substrate 101 (the lower face of the layer 115, in the orientation of FIG. 2C) are brought into contact with contact elements 111 flush with the face of the interconnect stack 109 opposite the read circuit 112 (the upper face of interconnect stack 109, in the orientation of FIG. 2C).

In particular, FIG. 2D illustrates a structure obtained at the end of a subsequent step of thinning the semiconductor substrate 101, from its face 101R.

For example, the semiconductor substrate 101 is thinned by chemical mechanical polishing. Once thinned, the substrate 101 has a thickness of between a few hundred nanometres and a few micrometres.

In particular, FIG. 2E illustrates a structure obtained at the end of a subsequent step of forming the optical concentrator(s) 103 on the side of the face 101R of the substrate 101.

Optical concentrators 103, for example, are manufactured using a “shape transfer” technique. For this purpose, structures identical or similar to the optical concentrators 103 are first formed in a resin layer previously deposited on the face 101R of the substrate 101. A subsequent etching step then transfers the relief of the resin layer to the face 101R of the substrate 101, the etching depth from the face 101R of the substrate 101 depending on the thickness of the overlying resin layer.

In the example shown, each pixel P1 of the sensor C1 comprises an optical concentrator 103 that is different from the optical concentrators 103 of the other pixels P1. However, this example is not limitative, as each optical concentrator 103 may, alternatively, be common to several pixels P1 of the sensor C1. Furthermore, in the example shown in FIG. 2E, the optical concentrators 103 are refractive microlenses, for example convergent. However, this example is not limitative, as the optical concentrators 103 can alternatively be diffractive lenses, Fresnel lenses, metasurfaces, etc. Those skilled in the art will be able to adapt the indications of the present description to realize these elements.

FIG. 2F illustrates a structure obtained at the end of a subsequent step of depositing the layer 133 on the side of the face 101R of the substrate 101.

By way of example, the layer 133 is made of an oxide, such as silicon oxide. After deposition, the layer 133 is planarized, for example by chemical mechanical polishing.

Although not shown, depositing a layer of a material with a refractive index different from that of layer 133, such as a nitride layer, e.g. silicon nitride, can be provided between manufacturing the optical concentrators 103 (FIG. 2E) and depositing the layer 133 (FIG. 2F). In this case, the nitride layer coats the entire face 101R of the substrate 101, for example, and the layer 133 coats the entire face of the nitride layer opposite the substrate 101. Those skilled in the art is able to determine the material and thickness of this layer so as to optimize the optical properties, for example to obtain an anti-reflective function, e.g. spectral filtering, at the detection wavelength of the pixels P1 of the sensor C1.

In particular, FIG. 2G illustrates a step of manufacturing the sensor C2. The sensor C2 can be manufactured before, at the same time as, or after the sensor C1.

The manufacturing of the sensor C2 is within the abilities of those skilled in the art from the indications of the present description. By way of example, the photodiodes 121 and readout circuits are first formed in the semiconductor substrate 123. The interconnection stack 125 is then formed, for example, on the side of the front face 123F of the substrate 123. Then, the structure previously described in relation to FIG. 2F is transferred, for example by molecular bonding, to the structure previously described in relation to FIG. 2G so as to join the sensor C2 to the sensor C1. The face of the stack 125 opposite the substrate 123 is thus maintained in contact with the face of the layer 133 opposite the substrate 101.

The semiconductor substrate 123 can then be thinned, for example by chemical mechanical polishing, on the side of its face opposite the substrate 101, and then passivated. Connections between the sensors C1 and C2, not shown, are then made on the periphery, for example using TSV (Through-Silicon Via) technology, to enable the transmission of pixel drive and power supply signals. Finally, the colour filters 129 and microlenses 131 are formed on the side of the rear face 123R of the substrate 123.

Although not illustrated, the optional CMOS substrate 119 comprising the memory and signal processing circuits can then be attached to the CMOS substrate 108, on the side of a face of the readout circuit 112 opposite the interconnection stack 109, for example after the colour filters 129 and microlenses 131 have been formed.

In the method described above in relation to FIGS. 2A-G, the substrate 101 is retained at the end of the steps of manufacturing the device 100. This advantageously allows taking advantage of the presence of the substrate 101 to perform light-concentrating optical functions.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove. In particular, the embodiments described are not limited to the particular examples of materials and dimensions mentioned in the present description.

What is claimed is:

1. A method of manufacturing a device for acquiring a 2D image and a depth image, the method comprising the following steps:
a) forming, on a first face of a first support semiconductor substrate, a first sensor comprising a plurality of depth pixels;
b) forming, in the first support substrate, on the side of a second face of the first substrate opposite the first face, at least one optical concentrator;
c) forming, in and on a second semiconductor substrate, a second sensor comprising a plurality of 2D image pixels; and
d) placing the second sensor right next the first support substrate on the side of the second face of the first support substrate.

2. The method according to claim 1, wherein, in step a), photodiodes of the depth pixels of the first sensor are formed in a region of semiconductor material.

3. The method according to claim 2, wherein the material of said region is a III-V or II-VI semiconductor.

4. The method according to claim 3, wherein said region is made of indium gallium arsenide.

5. The method according to claim 2, wherein said region is attached to the first support substrate, on the side of the first face of the first support substrate, prior to the formation of the photodiodes of the depth pixels.

6. The method according to claim 5, wherein said region is attached to the first support substrate via an oxide layer.

7. The method according to claim 1, further comprising, between steps a) and b), a step of bonding the first sensor, on the first face side of the first support substrate, to an interconnect stack forming part of a third CMOS substrate.

8. A device for acquiring a 2D image and a depth image, comprising:
a first sensor formed on a first face of a first semiconductor support substrate, the first sensor comprising a plurality of depth pixels, and at least one optical concentrator formed in the first support substrate, on the side of a second face of the first support substrate opposite the first face; and
attached to the first support substrate, on the side of the second face of the first support substrate, a second sensor formed in and on a second semiconductor substrate and comprising a plurality of 2D image pixels.

9. The device of claim 8, wherein each optical concentrator is a refractive microlens, a diffractive microlens, a Fresnel microlens, or a metasurface.

10. The device according to claim 8, wherein the second sensor is a colour image sensor, each 2D image pixel comprising a colour filter preferentially transmitting red, green or blue light.

11. The device according to claim 8, wherein the first and second substrates are made of monocrystalline silicon.

12. The device according to claim 8, wherein the depth pixels of the first sensor have a larger pitch than the 2D image pixels of the second sensor.
